(19) United States
(12) Patent Application Publication
(10) Pub. No.: US 2006/0199367 A1
(43) Pub. Date: Sep. 7, 2006

(54) SEMICONDUCTOR DEVICE AND MANUFACTURING METHOD THEREOF

(76) Inventors: Jim-Jey Huang, Tainan County (TW); Chih-Chien Liu, Taipei (TW); Feng-Yu Hsu, Tainan Hsien (TW); Jei-Ming Chen, Taipei County (TW); Kuo-Chih Lai, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,824

(22) Filed: Dec. 7, 2005

Related U.S. Application Data
(60) Provisional application No. 60/634,913, filed on Dec. 10, 2004.

(51) Int. Cl. H01L 21/4763

(52) U.S. Cl. 438/618; 438/643

(57) ABSTRACT

A manufacturing method of interconnect is provided. A dielectric layer is provided. A metal layer is formed in the dielectric layer. A fluorine-containing barrier layer is formed on the dielectric layer and covers the metal layer. The fluorine-containing barrier layer is formed by using chemical deposition method and introducing fluorine to the film in-situ.

### CROSS-REFERENCE TO RELATED APPLICATION

This application claims the priority benefits of U.S. provisional application titled “ARMOPHOUS SILICON CARBIDE BARRIER IN-SITU INTRODUCED F TO REDUCE K AND LEAKAGE” filed on Dec. 10, 2004, Ser. No. 60/634,913. All disclosures of this application are incorporated herein by reference.

### BACKGROUND OF THE INVENTION

1. Field of the Invention

The present invention relates to a semiconductor device and a fabrication method thereof. More particularly, the present invention relates to an interconnect structure and a fabrication method thereof.

2. Description of Related Art

As the semiconductor process enters the sub-micron territory, copper is introduced to replace aluminum as the material for forming an interconnect because the resist value of electromigration of copper is about 30 to 100 times of that of aluminum. Further, the resist value of via of copper is about 10 to 20 times lower than that of aluminum while the resistance of copper is about 30% lower than that of aluminum. However, copper easily diffuses into the dielectric layer under high temperature or an electric field. Accordingly, low K materials are normally used as the inter-metal dielectrics in the manufacturing of a copper conductive line to lower RC delay and to enhance electromigration. Since the etching of copper is difficult, dual damascene process is used to replace the traditional conductive line fabrication process for the manufacturing of a copper conductive line.

On the other hand, copper is easily oxidized in subsequent manufacturing processes. Accordingly, when a copper conductive line is fabricated in a dual damascene process, a barrier layer is formed to cover the surface of copper to prevent the oxidization of copper. The material of the barrier layer is typically an amorphous silicon carbide material or a nitrogenated silicon carbide material. However, the dielectric constant (k=4.0˜4.5) and the leakage current (>6×10⁻¹¹) of amorphous silicon carbide or nitrogenated silicon carbide are higher than a low dielectric constant (k<3) material. A higher dielectric constant lowers the effectiveness of the dielectric layer and a higher leakage current affects the time dependent dielectric breakdown (TDDB).

Conventionally, fluorine ions are implanted into the carbide material to improve the bias temperature performance. However, fluorine radicals discharged from plasma bond freely with the carbide material, which is harmful to the device. Another approach is to replace nitrogen with oxygen to form an oxygen-containing barrier layer. However, during the formation of the oxygen-containing barrier layer, copper is easily oxidized.

### SUMMARY OF THE INVENTION

At least one objective of the present invention is to provide an interconnect structure and a fabrication method for an interconnect structure in which the dielectric constant of the barrier layer can be lowered to obviate the occurrence of a current leakage to improve the yield and the reliability of the device.

The present invention provides a fabrication method for an interconnect structure. The method includes providing a dielectric layer, and a metal layer is formed in the dielectric layer. A fluorine-containing barrier layer is formed on the dielectric layer, covering the metal layer. The fluorine-containing barrier layer is formed by chemical vapor deposition with in-situ doping, for example.

In the above fabrication method for an interconnect, the fluorine-containing barrier layer includes, but not limited to, fluorinated silicon carbonitride or fluorinated silicon carbide.

In the above fabrication method for an interconnect, after the step of forming the metal layer in the dielectric layer and before the step of forming the fluorine-containing barrier layer, the method further includes forming a barrier layer on the dielectric layer, wherein the barrier layer covers the metal layer. The barrier layer includes an oxygen-free dielectric layer.

In the above fabrication method for an interconnect, the material of the barrier layer includes nitrogenated silicon carbide or silicon carbide. The fluorine-containing material includes fluorinated silicon carbonitride, fluorinated silicon carbide or fluorinated silicon oxycarbide.

In the above fabrication method for an interconnect, the barrier layer and the fluorine-containing barrier layer are formed in a same reaction chamber.

In the above fabrication method for an interconnect, the fluorine-containing barrier layer is formed with reacting gases that include a fluorine-containing gas, a silicon-containing gas, a carbon-containing gas. The fluorine-containing gas includes a carbon tetrafluoride gas or a silicon tetrafluoride gas, for example. The silicon-containing gas includes a silane gas, for example. The carbon-containing gas includes a carbon dioxide gas, for example.

In the above fabrication method for an interconnect, the fluorine-containing barrier layer is formed by using a nitrogen-containing gas as a reaction gas. The nitrogen-containing gas includes ammonia.

In the above fabrication method for an interconnect, a fluorine-containing barrier layer is formed on the metal layer. Since fluorine has high electronegativity, electrons can be captured. The dielectric constant and leakage current problem of the barrier layer can be improved. Moreover, the fluorine-containing dielectric material can be formed by chemical vapor deposition with in-situ implantation. Not only the manufacturing process is simpler, it is less harmful to the device, comparing with implanting fluorine ions using plasma. Additionally, the yield and reliability of the device are enhanced.

The present invention provides an interconnect, which includes a dielectric layer, a metal layer and a fluorine-containing barrier layer. The metal layer is disposed in the dielectric layer. The fluorine containing barrier layer is disposed above the dielectric layer and covers the metal layer.

In the above interconnect structure, the fluorine-containing material includes but not limited to fluorinated silicon carbonitride or fluorinated silicon carbide. A barrier layer is further disposed between the dielectric layer and the fluorine-containing barrier layer. The barrier layer is a dielectric layer that contains no oxygen.

In the above interconnect structure, the material that constitutes the barrier layer includes nitrogenated silicon carbide or silicon carbide. The fluorine-containing material includes fluorinated silicon carbonitride, fluorinated silicon carbide or fluorinated silicon oxycarbide, for example.

In the above interconnect structure, the barrier layer is about 200 angstroms thick. The fluorine-containing barrier layer is about 300 angstroms thick. The metal layer is formed with copper.

The above interconnect structure of the present invention is constructed with a fluorine-containing barrier layer. Since fluorine has high electronegativity, electrons can be captured. Accordingly dielectric constant and leakage current problems can be improved. The yield and the reliability of the device are also enhanced.

Several exemplary embodiments of the invention will now be described in detail with reference to the accompanying drawings. It is to be understood that the foregoing general description and the following detailed description of preferred purposes, features, and merits are exemplary and explanatory towards the principles of the invention only and are not restrictive of the invention, as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1E are schematic, cross-sectional views showing the steps for fabricating a metal interconnect of a semiconductor device according to an embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts. It is to be understood that both the foregoing general description and the following detailed description are exemplary, and are intended to provide further explanation of the invention as claimed.

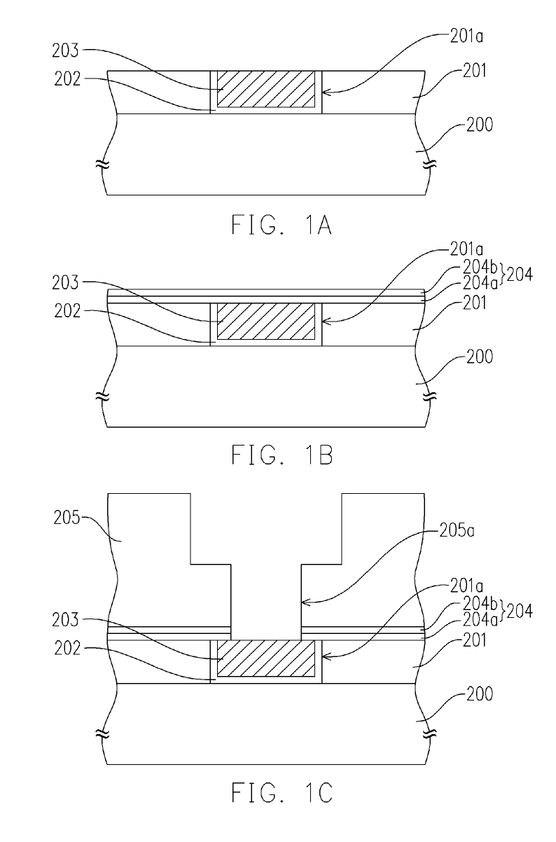

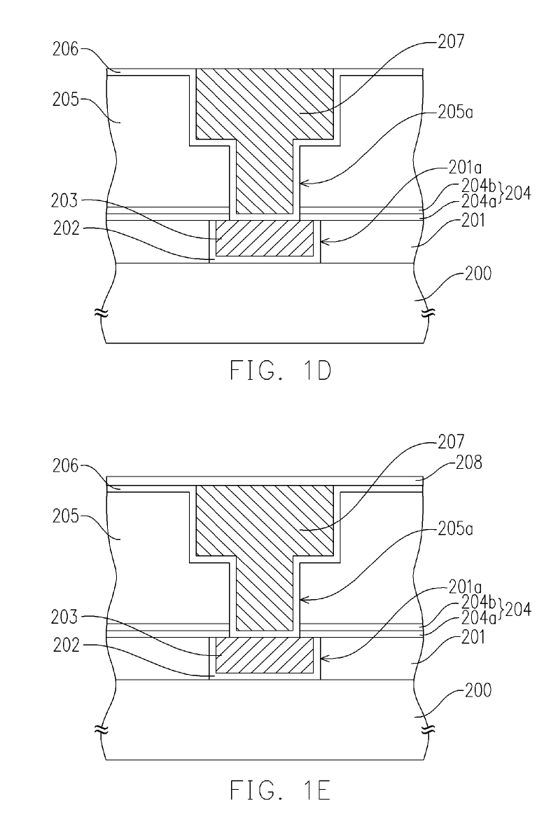

FIGS. 1A through 1E are schematic, cross-sectional views showing the steps for fabricating a metal interconnect of a semiconductor device according to an embodiment of the present invention.

Referring to FIG. 1A, a substrate 200 is provided (for simplification purposes, devices in the substrate 200 are omitted in the Figures). A dielectric layer 201 is formed over the substrate 200. The dielectric layer 201 is formed with silicon oxide or other low dielectric constant material (with a dielectric constant lower than 3), for example. The dielectric layer 201 is formed by chemical vapor deposition or spin-coating. An opening 201a that exposes the substrate 200 is then formed in the dielectric layer 201. The opening 201a is a via opening or a contact opening, for example. A glue layer 202 is further formed in the opening 201a. The glue layer 202 includes a tantalum nitride material, a titanium nitride material or a titanium silicon nitride material, for example. A copper layer is subsequently formed on the substrate 200. After removing the copper layer outside the opening 201a by chemical mechanical polishing, a metal layer 203 is formed.

Referring to FIG. 1B, a barrier layer 204 is formed on the dielectric layer 201. The barrier layer 204 at least covers the metal layer 203. The barrier layer 204 is constituted with a barrier layer 204a and a barrier layer 204b. The material of the barrier layer 204a includes an oxygen-free dielectric material, such as, nitrogenated silicon carbide, silicon carbide, fluorinated silicon carbonitride or fluorinated silicon carbide. The barrier layer 204a is about 200 angstroms thick. The material of the barrier layer 204b (fluorine-containing barrier layer) include fluorine-containing material, such as, fluorinated silicon carbonitride, fluorinated silicon carbide, fluorinated silicon oxycarbide, etc. The barrier layer is about 300 angstroms thick. In this embodiment, the barrier layer 204 is a dual layer structure. The barrier layer 204 can be a single layer structure or a multi layer structure. When the barrier layer 204 is a single layer structure, the material of the barrier layer 204 is a dielectric material that contains nitrogen but no oxygen, such as fluorinated silicon carbonitride or fluorinated silicon carbide, etc.

The barrier layer 204 is formed by chemical vapor deposition, while the fluorine-containing dielectric material is formed by introducing fluorine into the film in-situ.

As an example, when the material of the barrier layer 204a is silicon carbide and the material of the barrier layer 204b is fluorinated silicon carbide, a silicon-containing gas and a carbon-containing gas are introduced into a same reaction chamber as reaction gases to form a nitrogenated silicon carbide layer (barrier layer 204a). A fluorine-containing gas is then introduced into the same reaction chamber to form a fluorinated silicon carbide layer (barrier layer 204b).

When the material of the barrier layer 204a is nitrogenated silicon carbide and the material of the barrier layer 204b is fluorinated silicon carbonitride, a nitrogen-containing gas, a silicon-containing gas, a carbon-containing gas are introduced into a same reaction chamber as reaction gases to form a layer of nitrogenated silicon carbide (barrier layer 204a). A fluorine-containing gas is further introduced into a same reaction chamber to form fluorinated silicon carbonitride (barrier layer 204b).

When the material of the barrier layer 204a is silicon carbide, and the material of the barrier layer 204b is fluorinated silicon carbonitride, a nitrogen-containing gas, a silicon-containing gas, a carbon-containing gas are introduced into the same reaction chamber as reaction gases to form a layer of silicon carbide (barrier layer 204a). A fluorine-containing gas is then introduced into the same reaction chamber to form fluorinated silicon carbonitride (barrier layer 204b).

The above fluorine-containing gas includes a carbon tetrafluoride gas or a silicon tetrafluoride gas. The silicon-containing gas includes a silane gas, for example. The carbon-containing gas includes a carbon dioxide gas, for example. The nitrogen-containing gas includes an ammonia gas, for example.

Referring to FIG. 1C, another layer of dielectric layer 205 is formed over the substrate 200. This dielectric layer 205 is formed with silicon oxide material, for example, or other low dielectric constant material (dielectric constant lower than 4). The dielectric layer 205 is formed by chemical vapor deposition or spin coating.

Thereafter, an opening 205a that exposes the metal layer 203 is formed in the dielectric layer 205. The opening 205a is a damascene opening for forming a dual damascene structure or a trench of a metal conductive line, or a via or a contact opening for a plug, or an opening for any damascene structure. The opening 205a can be formed by defining the trench first, defining the via first, or a self-aligned formation of the trench and the via. In this embodiment, the via is defined first in which a photoresist layer is formed on the dielectric layer 205, followed by defining and etching the photoresist layer to form a via opening in the dielectric layer 205 until the barrier layer 204 is exposed. The above-mentioned photoresist layer is then removed. Another photoresist layer (not shown) is formed above the dielectric layer 205. This photoresist layer is defined and the dielectric layer 205 is etched to form a trench above the via opening. Thereafter, a portion of the barrier layer 204 is removed to expose the metal layer 203. The formation of the opening 205a is thereby completed.

Continuing to FIG. 1D, a glue layer 205 is formed in the opening 205a. The material of the glue layer 206 includes tantalum nitride, titanium nitride or titanium silicon nitride. The glue layer 206 is formed by chemical vapor deposition. A copper layer is then formed on the substrate 200. After removing the copper layer outside the opening 205a using chemical mechanical polishing, a metal layer 207 is formed.

Referring to FIG. 1E, a barrier layer 208 is formed on the dielectric layer 205. The barrier layer 208 covers the metal layer 207. The structure and the formation method of the barrier layer 208 are similar to those of the barrier layer 204, and the details thereof will not be reiterated herein.

In the fabrication method of an interconnect of the present invention, the materials of the barrier layer 204 and the barrier layer 208 are selected from fluorine-containing dielectric materials. Since fluorine has high electronegativity, electrons can be captured. The dielectric constant and current leakage problem of the barrier layer can be improved. Moreover, the fluorine-containing material is formed by chemical vapor deposition with in-situ implantation. Not only the manufacturing process is simpler, it is less harmful to the device comparing with implanting fluorine ions using plasma. Accordingly, the yield and the reliability of the device are enhanced.

Still referring to FIG. 1E, the interconnect structure of the present invention includes a substrate 200, a dielectric layer 201, a glue layer 202, a metal layer 203, a barrier layer 204 (barrier layer 204a and barrier layer 204b), a dielectric layer 205, a glue layer 206, a metal layer 207 and a barrier layer 208.

The dielectric layer 201 is disposed on the substrate 200, for example. The dielectric layer 201 is a silicon oxide material, for example, or other low dielectric constant material (dielectric constant lower than 4). The metal layer 203 is disposed in the dielectric layer 201. The metal layer 203 is copper, for example. The glue layer 202 is disposed between the metal layer 203 and the dielectric layer 201. The material of the glue layer 202 includes but not limited to tantalum nitride, titanium nitride or titanium silicon nitride.

The barrier layer 204 (barrier layer 204a and barrier layer 204b) is disposed on the dielectric layer 201. The barrier layer 204 is formed with the barrier layer 204a and the barrier layer 204b, for example. The material of the barrier layer 204a includes an oxygen-free dielectric material, for example, nitrogenated silicon carbide, silicon carbide, fluorinated silicon carbonitride, or fluorinated silicon carbide, etc. The barrier layer 204a is about 200 angstroms thick. The material of the barrier layer 204b (fluorine-containing barrier layer) includes fluorine-containing material, such as, fluorinated silicon carbonitride, fluorinated silicon carbide, or fluorinated silicon oxycarbide, etc. The barrier layer 204b is about 300 angstroms thick. In this embodiment, the barrier layer 204 is a dual layer structure as an example. The barrier layer 204 can be a single layer structure or a multi layer structure. When the barrier layer 204 is a single layer structure, the material that constitutes the barrier layer 204 includes dielectric materials that contain nitrogen but no oxygen, such as fluorinated silicon carbonitride or fluorinated silicon carbide, etc.

The dielectric layer 205 is disposed on the barrier layer 204. The material of the dielectric layer 205 includes silicon oxide material or other low dielectric constant material (dielectric constant lower than 4). The metal layer 207 is disposed in the dielectric layer 205 and is electrically connected with the metal layer 203. The metal layer 208 is copper, for example. The glue layer 206 is disposed between the metal layer 207 and the dielectric layer 205 and between the metal layer 207 and the metal layer 203. The glue layer 206 is constituted with a tantalum nitride material, a titanium nitride material or a silicon nitride material, for example. The barrier layer 208 is disposed on the dielectric layer 205, covering the metal layer 207. The structure and the material of the barrier layer 208 are similar to those of the barrier layer 204, and the details thereof will not be reiterated herein.

In the interconnect structure of the present invention, the barrier layer 204 and the barrier layer 208 are formed with materials that are selected from fluorine-containing dielectric materials. Since fluorine has high electronegativity for capturing electrons, the dielectric constant and the current leakage problem of the barrier layers can be improved. The yield and the reliability of the device are thus enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method for an interconnect, comprising:
providing a dielectric layer;
forming a metal layer in the dielectric layer;
forming a fluorine-containing barrier layer on the dielectric layer, wherein the fluorine-containing barrier layer covers the metal layer, and the fluorine-containing barrier layer is formed by a chemical vapor deposition process with an in-situ doping.

2. The method of claim 1, wherein the fluorine-containing layer is formed with fluorinated silicon carbonitride or fluorinated silicon carbide.

3. The method of claim 1, wherein after the step of forming the metal layer in the dielectric layer and before the step of forming the fluorine-containing barrier layer on the dielectric layer, the method further comprises forming a barrier layer on the dielectric layer to cover the metal layer.

4. The method of claim 3, wherein the barrier layer comprises an oxygen-free dielectric layer.

5. The method of claim 3, wherein a material that constitutes the barrier layer comprises nitrogenated silicon carbide or silicon carbide, and a material that constitutes the fluorine-containing barrier layer comprises fluorinated silicon carbonitride, fluorinated silicon carbide or fluorinated silicon oxycarbide.

6. The method of claim 3, wherein the barrier layer and the fluorine-containing barrier layer are formed in a same reaction chamber.

7. The method of claim 3, wherein the fluorine-containing barrier layer is formed with reaction gases that comprise a fluorine-containing gas, a silicon-containing gas or a carbon-containing gas.

8. The method of claim 7, wherein the fluorine-containing gas comprises carbon tetrafluoride or silicon tetrafluoride.

9. The method of claim 7, wherein the silicon-containing gas comprises a silane gas.

10. The method of claim 7, wherein the carbon-containing gas comprises a silicon dioxide gas.

11. The method of claim 7, wherein the fluorine-containing barrier layer is formed with a reaction gas that comprises a nitrogen-containing gas.

12. The method of claim 11, wherein the nitrogen-containing gas comprises ammonia.

13. An interconnect structure, comprising:
a dielectric layer;
a metal layer, disposed in the dielectric layer;
a fluorine-containing barrier layer, disposed on the dielectric layer, wherein the fluorine-containing barrier layer covers the metal layer.

14. The interconnect structure of claim 13, wherein the fluorine-containing barrier is formed with a material that comprises fluorinated silicon carbonitride or fluorinated silicon carbide.

15. The interconnect structure of claim 13, wherein a barrier layer is further disposed between the dielectric layer and the fluorine-containing barrier layer.

16. The interconnect structure of claim 15, wherein the barrier layer comprises a dielectric layer that contains no oxygen.

17. The interconnect structure of claim 15, wherein the barrier layer is constituted with a material that comprises nitrogenated silicon carbide or silicon carbide, and the fluorine-containing barrier layer is constituted with a material that comprises fluorinated silicon carbonitride, fluorinated silicon carbide or fluorinated silicon oxycarbide.

18. The interconnect structure of claim 15, wherein the barrier layer is about 200 angstroms thick.

19. The interconnect structure of claim 15, wherein the fluorine-containing barrier layer is about 300 angstroms thick.

20. The interconnect structure of claim 15, wherein the metal layer is copper.
